(19) United States
(12) Patent Application Publication
(10) Pub. No.: US 2013/0333414 A1
(43) Pub. Date: Dec. 19, 2013

(54) SYSTEM FOR COOLING ELECTRONIC DEVICE

(71) Applicants: Kenichi Inaba, Tokyo (JP); Minoru Yoshikawa, Tokyo (JP)

(72) Inventors: Kenichi Inaba, Tokyo (JP); Minoru Yoshikawa, Tokyo (JP)

(21) Appl. No.: 13/818,091

(22) PCT Filed: Jul. 5, 2011
(86) PCT No.: PCT/JP2011/065337

§ 371 Date: Aug. 28, 2013

(30) Foreign Application Priority Data
Aug. 31, 2010 (JP) 2010-193733

(51) Int. Cl. H05K 7/20

(52) U.S. Cl. CPC H05K 7/20
USPC 62/513

(57) ABSTRACT

A system for cooling an electronic device of the present invention cools air warmed by exhaust heat of an electronic device, and includes an evaporator, a condenser, a gas flow channel, and a liquid flow channel. The evaporator is provided in a direction in which air is blown out by the electronic device, and causes a liquid coolant to undergo a phase transition to a gaseous coolant by absorbing heat of the air blown out from the electronic device. The condenser causes the gaseous coolant to undergo a phase transition to a liquid coolant by releasing heat of the gaseous coolant. The gas flow channel flows the gaseous coolant undergone the phase transition by the evaporator, into the condenser. The liquid flow channel flows the liquid coolant undergone the phase transition by the condenser, into the evaporator. The condenser is arranged above the evaporator.

### TECHNICAL FIELD

The present invention relates to a system for cooling an electronic device that cools air that has been warmed by the exhaust heat of an electronic device.

### BACKGROUND ART

In recent years, with improvements in information processing technology and development of the Internet environment, the amount of information processing that is required is increasing. In connection with such trends, the data center business that involves installing and operating devices such as servers, communications equipment, fixed-line telephones, IP phones used for the Internet, is drawing attention. In the server room of this data center, numerous electronic devices such as computers are installed. Generally, among methods of installing electronic equipment in a server room, the use of a rack-mounted system has become predominant. A rack-mounted system is standardized by JIS or EIA, and is a system of installing flat-form electronic devices in a stacked manner in a rack.

In order to sufficiently secure the space of the server room, it is desired for as many electronic devices as possible to be mounted in a rack. For that reason, it is necessary for the height of each electronic device to be low. Generally, the height of an electronic device such as a 1U (unit) server or blade server that is called a rack-mounted server is around 40 millimeters.

As stated above, since it is desired to lower the height of the electronic device, mounting heat sinks directly above LSIs (large-scale integrations) or ICs (integrations) for cooling of the electronic device is not preferred. Therefore, as a method of cooling an electronic device, a method is used that provides a heat moving structure such as a heat pipe in an electronic device and a heat radiating structure such as fins at the end portion of that heat moving structure (for example, refer to Patent Document 1). With this structure, it is possible to move heat to a place removed from the LSI and IC by the heat moving structure, and radiate the heat to outside of the electronic device via the heat radiating structure.

Patent Document 2 discloses a cooling system. In this cooling system, a first heat transport member that conveys heat generated by a semiconductor device to the outside is provided on an electronic circuit board of an electronic device. Also, a second heat transport member that conveys heat from the first heat transport member to the outside is provided in a housing of the electronic device. Moreover, a heat radiating member that radiates heat from the second heat transport member to the outside of the housing is provided.

Patent Document 3 discloses that the second heat transport member and the heat radiating member may constitute a refrigeration cycle.

Patent Document 3 discloses a method of arranging evaporators that constitute a refrigeration cycle that cools heat that electronic devices give off, in a rack in which are arranged electronic devices provided with fans for dissipating generated heat.

### PRIOR ART DOCUMENTS

### Patent Documents

[Patent Document 1] Japanese Unexamined Patent Application, First Publication No. 2007-088282
[Patent Document 2] Japanese Unexamined Patent Application, First Publication No. 2010-079401
[Patent Document 3] Japanese Unexamined Patent Application, First Publication No. 2009-193137

### SUMMARY OF THE INVENTION

### Problem to be Solved by the Invention

However, simply dissipating heat generated from an electronic device to outside of the electronic device, in the manner of the methods disclosed in Patent Document 1 and Patent Document 2 leads to a rise in the air temperature of the server room in which that electronic devices are arranged. As a result, there is the problem of the load on the air conditioning that performs cooling in the sever room being increased.

By cooling the exhaust air of an electronic device with evaporators provided in the server rack as in the manner disclosed in Patent Document 3, it is possible to suppress a rise in the air temperature of the server room in which the electronic devices are installed. However, with the method disclosed in Patent Document 3, it is necessary to provide, between a condenser that performs cooling of the coolant and the evaporators, a compressor that compresses the coolant that is evaporated by the evaporators and circulates the coolant between the condenser and the evaporators. As a result, there is the problem of the cooling device becoming huge.

### Means for Solving the Problem

The present invention has been achieved in view of the above circumstances. A system for cooling an electronic device of the present invention cools air warmed by exhaust heat of an electronic device, and includes an evaporator, a condenser, a gas flow channel, and a liquid flow channel. The evaporator is provided in a direction in which air is blown out by the electronic device, and causes a liquid coolant to undergo a phase transition to a gaseous coolant by absorbing heat of the air blown out from the electronic device. The condenser causes the gaseous coolant to undergo a phase transition to a liquid coolant by releasing heat of the gaseous coolant. The gas flow channel flows the gaseous coolant undergone the phase transition by the evaporator, into the condenser. The liquid flow channel flows the liquid coolant undergone the phase transition by the condenser, into the evaporator. The condenser is arranged above the evaporator.

### Effect of the Invention

According to the present invention, since the evaporator performs heat exchange with the heat of the air that is blown out from the electronic device, it is possible to lower the temperature of the air that is warmed by exhaust heat of the electronic device, and possible to suppress a rise in the air temperature of the room in which the electronic device is installed.

Moreover, according to the present invention, since the condenser is disposed above the evaporator, the height of the liquid level in the condenser is higher than the height of the liquid level in the evaporator. Thereby, the liquid coolant that is stored in the condenser passes through the liquid flow channel by gravitational force, and flows into the evaporator. On the other hand, the gas coolant that is stored in the evaporator passes through the gas flow channel by gravitational force and flows into the condenser. For that reason, the system for cooling an electronic device of the present invention can cause the coolant to circulate between the condenser and the evaporator even if a compressor is not provided.

### BRIEF DESCRIPTION OF THE DRAWINGS

FIG. 1 is a perspective view of a system for cooling an electronic device according to a first exemplary embodiment of the present invention.

FIG. 2 is a configuration diagram of the system for cooling an electronic device according to the first exemplary embodiment of the present invention.

FIG. 3 is a diagram that shows a cross section of the evaporator shown in FIG. 1.

FIG. 4 is a diagram that shows a cross section of the condenser shown in FIG. 1.

FIG. 5A is a diagram that shows an arrangement of the tubes shown in FIG. 1.

FIG. 5B is a diagram that shows an arrangement of the tubes shown in FIG. 1.

FIG. 6 is a perspective view of a system for cooling an electronic device according to a second exemplary embodiment of the present invention.

FIG. 7 is a perspective view of a system for cooling an electronic device according to a third exemplary embodiment of the present invention.

### EMBODIMENTS FOR CARRYING OUT THE INVENTION

Hereinbelow, exemplary embodiments of the present invention shall be described in detail while referring to the drawings.

### First Exemplary Embodiment

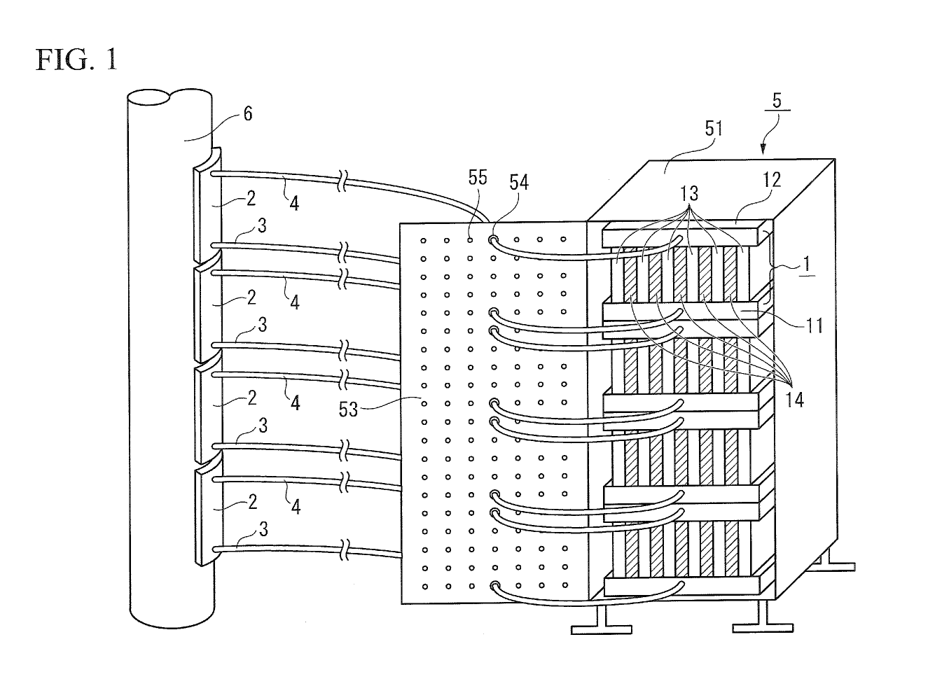

FIG. 1 is a perspective view of a system for cooling an electronic device (electronic device cooling apparatus) according to the first exemplary embodiment of the present invention.

The system for cooling an electronic device is a system that cools air that is warmed by exhaust heat of the electronic device.

As shown in FIG. 1, the system for cooling an electronic device includes a plurality of evaporators 1 and a plurality of condensers 2. The evaporator 1 gasifies coolant by heat exchange between coolant that is stored therein and air that the electronic device blows out. The condenser 2 liquefies the coolant that is stored therein.

The evaporators 1 are provided in a storage rack 5 that holds electronic devices, and cool air that is blown out from the electronic devices by latent heat of evaporation of the coolant.

The condensers 2 are attached at positions respectively higher than the evaporators 1, on the surface of a cooling water pipe 6 (cooling pipe) for an air conditioner that is provided in a data center or server room that houses the storage rack 5. The condensers 2 change the phase of the gas coolant to a liquid by cooling the coolant that is stored therein. At this time, the temperature of the cooling water that flows through the cooling water pipe 6 is lower than the boiling point of the coolant that is held within the condensers 2.

The cooling water pipe 6 to which the condensers 2 are attached is arranged in a manner straddling the data center or server room that houses the storage rack 5 and the outside of the data center or server room. That is to say, at least a portion of the cooling water pipe 6 is exposed to the outside of the data center or server room.

Also, the lower portion of the evaporator 1 (lower container) and the lower portion of the condenser 2 are connected by a tube 3. The upper portion of the evaporator 1 (upper container) and the upper portion of the condenser 2 are connected by a tube 4. The tube 3 functions as a liquid flow channel that causes the coolant that the condenser 2 has made undergo a phase transition from a gas to a liquid to flow to the evaporator 1. The tube 4 functions as a gas flow channel that causes the coolant that the evaporator 1 has made undergo a phase transition from a liquid to a gas to flow to the condenser 2.

In the present exemplary embodiment, a material that has flexibility and excellent chemical resistance such as a butyl tube, a silicon tube, a nylon tube, a fluorine tube and the like is used for these tubes 3 and 4. As the coolant, a coolant that has a low boiling point and high insulating properties such as fluorocarbon or hydrofluoroether is used.

The evaporator 1 and the condenser 2 form an airtight system by being connected by the pair of tubes 3 and 4. The interior of the airtight system that is formed by the evaporator 1 and the condenser 2 and the pair of tubes 3 and 4 is filled with the coolant. The interior pressure of the airtight system is held in a state that is lower than the atmospheric pressure. This is realized by creating a vacuum state by lowering the pressure of the airtight system after pouring a liquid coolant in the interior of the airtight system. By making the internal pressure of the airtight system lower than the atmospheric pressure in this manner, the boiling point (saturation vapor pressure) of the coolant that has been enclosed in the interior decreases. In particular, in the case of using fluorocarbon or hydrofluoroether or the like as the coolant, the boiling point falls below room temperature. Thereby, it is possible to cause the coolant in the interior of the evaporator 1 to evaporate by the evaporator 1 performing heat exchange with the air that is warmed by the exhaust heat of the electronic device 1.

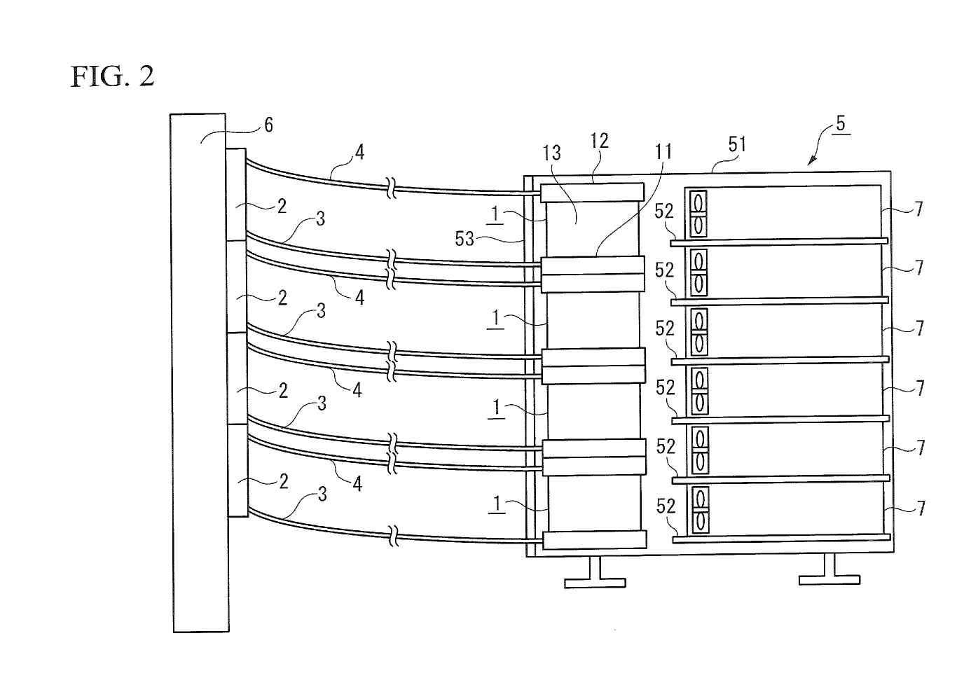

FIG. 2 is a configuration diagram of the system for cooling an electronic device according to the first exemplary embodiment of the present invention.

The evaporator 1 is provided in the storage rack 5 that houses the electronic device 7. The storage rack 5 includes a housing 51 that forms the external body, a plurality of installation shelves 52 that are provided at the front side of the housing 51 and used for installing the electronic devices 7, and a rear door 53 that is provided at the rear side of the housing 51 and freely opens and closes. The evaporator 1 is placed between the installation shelf 52 and the rear door 53 of the storage rack 5.

A fan for blowing out exhaust heat of the electronic device 7 to the outside of the electronic device 7 is mounted at the electronic device 7 that is installed on the installation shelf 52. This electronic device 7 is placed on the installation shelf 52 so that the air that is blown out from the electronic device 7 is discharged to the outside of the housing 51 via the evaporator 1.

FIG. 1 shows the state of the rear door 53 being opened. When actually in use, the rear door 53 is in the closed state, and the evaporators 1 are covered by the rear door 53. A plurality of through holes 54 and a plurality of exhaust holes 55 are provided in the rear door 53. The tubes 3 and 4 are passed through the through holes 54. The exhaust holes 55 exhaust to the outside of the housing 51 the air that the electronic devices 7 blow out. By passing the tubes 3 and 4 through the through holes 54, it is possible to exchange the coolant between the evaporators 1 and the condensers 2 even when the rear door 53 is closed. Due to the rear door 53 having the exhaust holes 55, even when the rear door 53 is closed, it is possible to ensure air flow between the inside and outside of the storage rack 5.

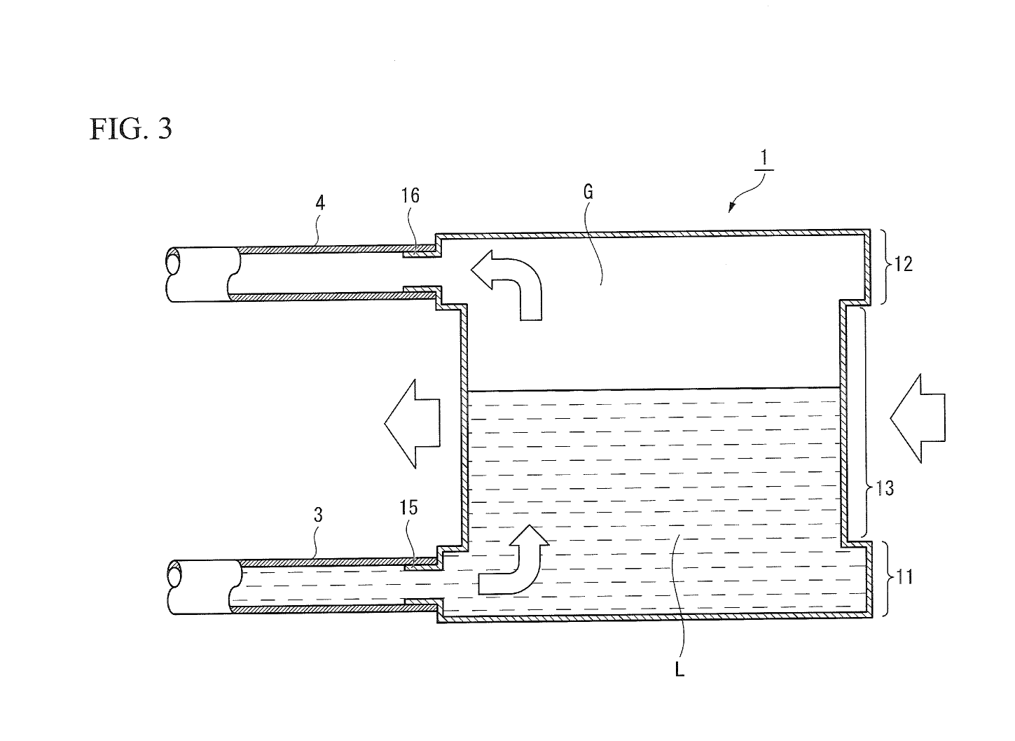

FIG. 3 is a diagram that shows a cross section of the evaporator 1.

A gaseous coolant G and a liquid coolant L are held in the evaporator 1. The evaporator 1 includes a lower container 11 that is connected to the tube 3, an upper container 12 that is connected to the tube 4, and an evaporator tube 13 that joins the lower container 11 and the upper container 12. As shown in FIG. 1, the lower container 11 and the upper container 12 are connected by a plurality of the evaporator tubes 13. Heat receiving fins 14 are provided between the evaporator tubes 13. The heat receiving fins 14 are corrugated fins or the like, and promote heat exchange between the air that the electronic device 7 blows out and the coolant that is held in the evaporator tube 13. The components of the evaporator 1 are formed with metal having a high thermal conductivity such as copper or aluminum.

A flow-in hole 15 through which the coolant flows in from the tube 3 is provided at the portion of the lower container 11 that faces the rear door 53. A flow-out hole 16 through which the coolant flows out to the tube 4 is provided at the portion of the upper container 12 that faces the rear door 53.

The heat receiving fins 14 are joined to the evaporator tubes 13 by brazing or soldering. It is possible to increase the amount of heat transport of latent heat that the coolant absorbs from the air during evaporation, by making the fin pitch of the heat receiving fins 14 small (that is to say, by narrowing the interval between the fins). On the other hand, when the fin pitch of the heat receiving fins 14 is made small, the ventilation resistance of the air that is blown out from the electronic device 7 increases, and the wind velocity decreases. For that reason, it is necessary to form fins so as to achieve a ventilation resistance in which the operating temperature of components such as the LSIs and ICs of the electronic device 7 does not exceed the allowable temperature.

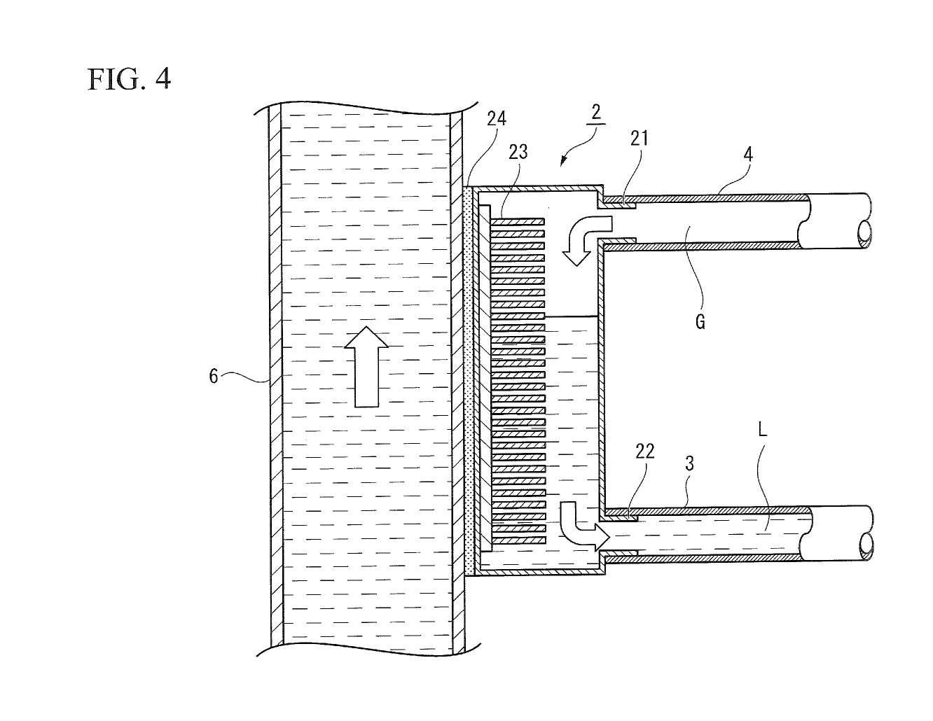

FIG. 4 is a diagram that shows a cross section of the condenser 2.

The gaseous coolant G and the liquid coolant L are held in the condenser 2. The condenser 2 is formed with metal having a high thermal conductivity such as copper or aluminum. A flow-in hole 21 through which the coolant flows in from the tube 4 and a flow-out hole 22 that causes the coolant to flow out to the tube 3 are formed in the condenser 2. On the inner wall of the condenser 2, heat dissipating fins 23 are screw fastened at a location facing the cooling water pipe 6. The heat dissipating fins 23 promote heat exchange between the cooling water that flows through the cooling water pipe 6 and the coolant that is held in the interior of the condenser 2.

The heat dissipating fins 23 have a structure that increases the contact surface area with the coolant, such as plate-type fin or a pin fin structure that is formed with a metal having a high thermal conductivity such as copper or aluminum.

The condenser 2 is attached to the cooling water pipe 6 via a TIM (thermal interface material) 24, in order to raise the efficiency of the heat exchange between the heat dissipating fins 23 and the cooling water pipe 6. That is to say, the TIM 24 is provided between the condenser 2 and the cooling water pipe 6. Provided the thermal conductivity is high, a TIM of any type may be used for the TIM 24, such as a grease type or a sheet type.

Next, the operation of the system for cooling an electronic device according to the present invention shall be described.

When the electronic device 7 that is housed in the storage rack 5 blows out air that has been warmed by the exhaust heat, that air is discharged to outside the storage rack 5 via the evaporator 1 and the rear door 53.

When that air passes the evaporator 1, the heat of the air is transferred to the evaporator tubes 13 via the heat receiving fins 14 of the evaporator 1. The heat that is transferred to the evaporator tubes 13 causes the temperature of the coolant that is held inside of the evaporator tubes 13 to increase. As described above, the internal pressure of the airtight system that is constituted from the evaporator 1, the condenser 2, and the pair of tubes 3 and 4 is lower than the atmospheric pressure. For this reason, the temperature of the coolant exceeds the boiling point by the heat from the heat receiving fins 14, and the liquid coolant evaporates.

At this time, the liquid coolant absorbs the latent heat from the air that the electronic device 7 blows out due to the phase change to a gas. Thereby, it is possible to lower the temperature of the air that the electronic device 7 has blown out, and it is possible to inhibit a rise in the air temperature of the room in which the electronic device 7 is installed.

The liquid coolant becomes a gaseous coolant by absorbing latent heat. This gaseous coolant travels along the evaporator tube 13 by buoyant force, and moves to the upper container 12. The gaseous coolant that has reached the upper container 12 flows out to the tube 4. The gaseous coolant that has flowed into the tube 4 flows out to the condenser 2 that is installed above than the evaporator 1 by buoyant force.

The gaseous coolant that has flowed into the condenser 2 dissipates heat to the cooling water that flows through the cooling water pipe 6, via the heat dissipating fins 23 that are provided in the interior of the condenser 2 and the TIM 24. By dissipating heat to the heat dissipating fins 23, the temperature of the gaseous coolant falls below the boiling point, and the gaseous coolant condenses. At this time, the gaseous coolant imparts latent heat to the cooling water pipe 6 in order to undergo a phase change to a liquid. The heat that has been imparted to the cooling water pipe 6 is transmitted to the cooling water that flows through the cooling water pipe 6, and is discharged to the outside of the data center or server room by the flow of the cooling water.

The gaseous coolant becomes a liquid coolant by imparting latent heat. This liquid coolant moves downward in the condenser 2 by gravitational force. The liquid coolant that has reached the bottom of the condenser 2 flows out to the tube 3. The liquid coolant that has flowed into the tube 3 flows out to the lower container 11 of the evaporator 1 that is installed lower than the condenser 2 by gravitational force.

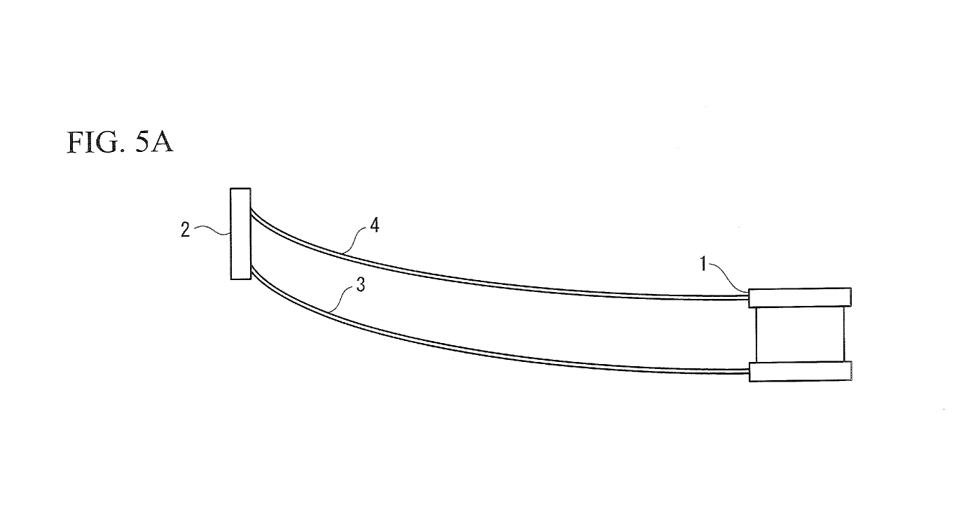

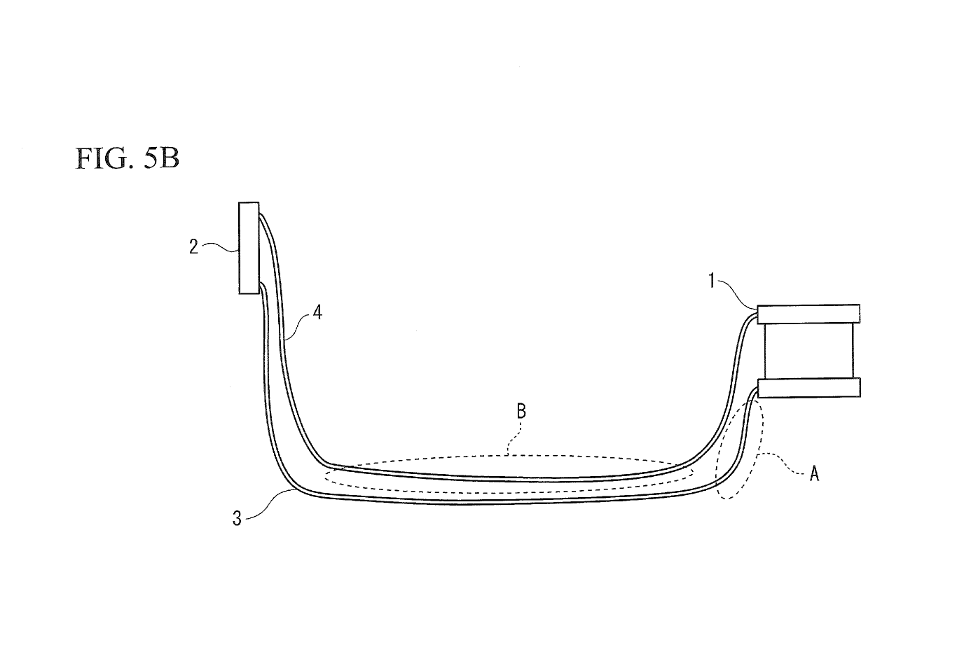

FIGS. 5A and 5B are diagrams that show the arrangement of the tubes 3 and 4.

The pair of tubes 3 and 4 that connect the evaporator 1 and the condenser 2 preferably do not have a location that sags downward in a convex manner with respect to a horizontal line, as shown in FIG. 5A. That is to say, the tubes 3 and 4 preferably extend gradually downward heading from the condenser 2 to the evaporator 1.

In the case of the tube 3 sagging downward in a convex manner with respect to a horizontal line as shown in FIG. 5B, the liquid coolant comes to flow against gravitational force at the portion enclosed by the dotted line A. For that reason, the velocity of the coolant that flows in the airtight system falls, and there is a risk of the circulation stagnating. Also, as shown in FIG. 5B, in the case of the tube 4 sagging downward in a convex manner with respect to a horizontal line, due to the gaseous coolant colliding with the wall surface of the tube 4, a pressure loss results, causing the gaseous coolant to liquefy, there is a risk of the liquid coolant stagnating in the portion enclosed by the dotted line B.

For these reasons, it is preferable that the tube 3 and the tube 4 do not have a location that sags downward in a convex manner with respect to a horizontal line.

In this manner, according to the present exemplary embodiment, the evaporator 1 performs heat exchange with the air that is warmed by the exhaust heat of the electronic device 7. For this reason, the temperature of the air decreases, and it is possible to inhibit a rise in the air temperature of the room in which the electronic device 7 is installed. Thereby, it is possible to restrict the cooling capacity by the air conditioner that is installed in a data center or server room, and it is possible to achieve electrical power saving of the air conditioner.

By using the system for cooling an electronic device according to the present exemplary embodiment, it was achieved to receive 40 percent to 60 percent of the heat that the electronic device 7 generated. Also, by using the system for cooling an electronic device according to the present exemplary embodiment, it was achieved to lower the exhaust air temperature from the storage rack 5 by a maximum of 15° C.

Also, according to the present exemplary embodiment, since the condenser 2 is arranged above the evaporator 1, the height of the liquid level in the condenser 2 is higher than the liquid level in the evaporator 1. Thereby, the liquid coolant that is held in the condenser 2 travels through the tube 3 by gravitational force, and flows to the evaporator 1. On the other hand, the gaseous coolant that is held in the evaporator 1 travels through the tube 4 by gravitational force, and flows to the condenser 2. For that reason, the system for cooling an electronic device can cause coolant to circulate between the condenser 2 and the evaporator 1 without a compressor.

Also, according to the present exemplary embodiment, the condenser 2 is provided on the surface of the cooling water pipe through which circulates cooling water with a lower temperature than the boiling point of the refrigerant that is held therein. Thereby, the condenser 2 can cause the gaseous coolant to efficiently condense.

Also, according to the present exemplary embodiment, the cooling water pipe is arranged in a manner straddling the inside of the server room or data center in which the electronic device 7 is installed and the outside of the server room or data center. Thereby, the heat that the condenser 2 releases to the cooling water that flows through the cooling water pipe can be discharged to the outside of the server room or data center.

Also, according to the present exemplary embodiment, the evaporator 1 provided in the direction in which air is blown out by the electronic device 7 that is placed on the installation shelf 52 (to the fore in the direction in which air is blown out) inside of the storage rack 5, while the condenser 2 is provided outside of the storage rack 5. Thereby, it is possible to lower the temperature of the air that is discharged from the storage rack 5, and it is possible to cause the heat that is discharged from the condenser 2 to not build up inside the storage rack 5.

Also, according to the present exemplary embodiment, the evaporator 1 includes heat receiving fins 14 that promote heat exchange between the air that the electronic device 7 blows out and the liquid coolant. Thereby, the evaporator 1 can efficiently cause the liquid coolant to evaporate.

Also, according to the present exemplary embodiment, the condenser 2 includes heat dissipating fins 23 that promote heat exchange between the cooling water that flows through the cooling water pipe 6 and the gaseous coolant. Thereby, the condenser 2 can efficiently cause the gaseous coolant to condense.

Also, according to the present exemplary embodiment, the tube 3 and the tube 4 have flexibility. Thereby, it is possible to simplify their arrangement during installation of the storage rack 5 and during moving, and it is possible to open and close the rear door 53 of the storage rack 5.

### Second Exemplary Embodiment

Next, a second exemplary embodiment of the present invention shall be described. In the second exemplary embodiment, the constituent elements that are the same as the first exemplary embodiment are denoted by the same reference symbols, with detailed descriptions thereof being omitted.

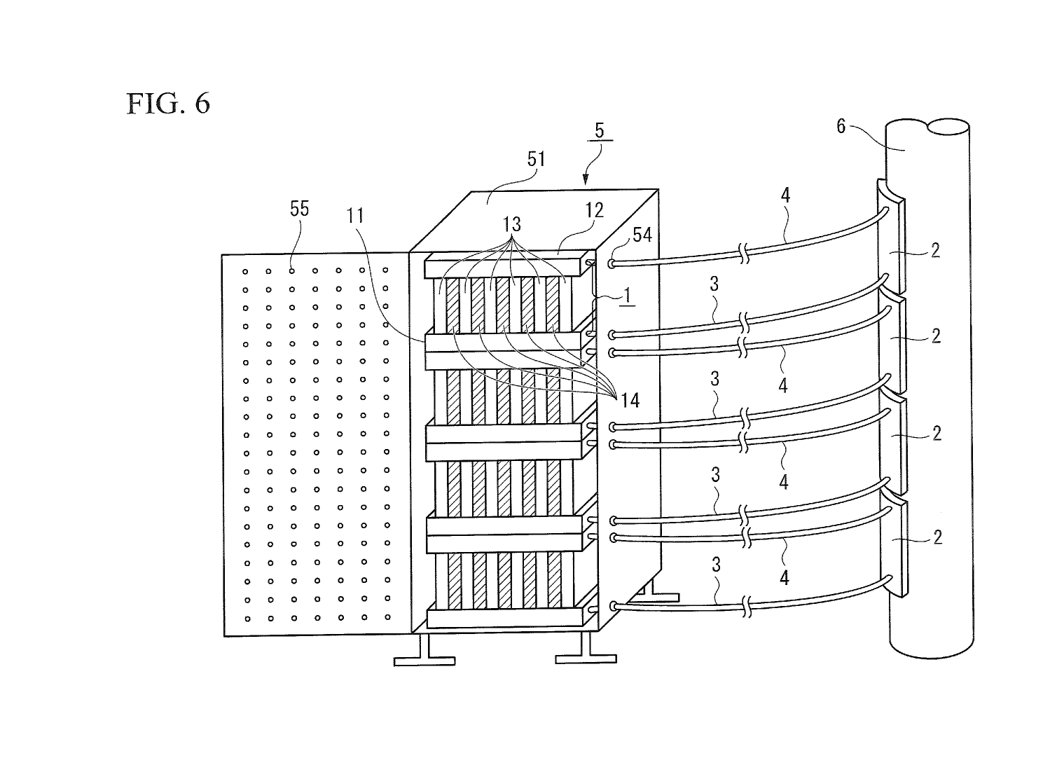

FIG. 6 is a perspective view of the system for cooling an electronic device according to the second exemplary embodiment of the present invention.

The storage rack 5 of the system for cooling an electronic device according to the second exemplary embodiment differs from the first exemplary embodiment in not including the through holes 54 in the rear door 53, and instead including the through holes 54 in a side surface of the housing 51. Also, the flow-in hole and the flow-out hole of the evaporator 1 are not provided at portions of the evaporator 1 facing the rear door 53, and instead a pair of the tubes 3 and 4 that are provided at the side surface of the evaporator 1 connect the evaporator 1 and the condenser 2 via through holes 54 in the side surface of the housing 51.

According to the exemplary embodiment, even in the case of not being able to secure the space for arranging the tubes 3 and 4 at the front of the rear door 53, it is possible to apply the system for cooling an electronic device.

### Third Exemplary Embodiment

Next, a third exemplary embodiment of the present invention shall be described. In the third exemplary embodiment, the constituent elements that are the same as the first exemplary embodiment are denoted by the same reference symbols, with detailed descriptions thereof being omitted.

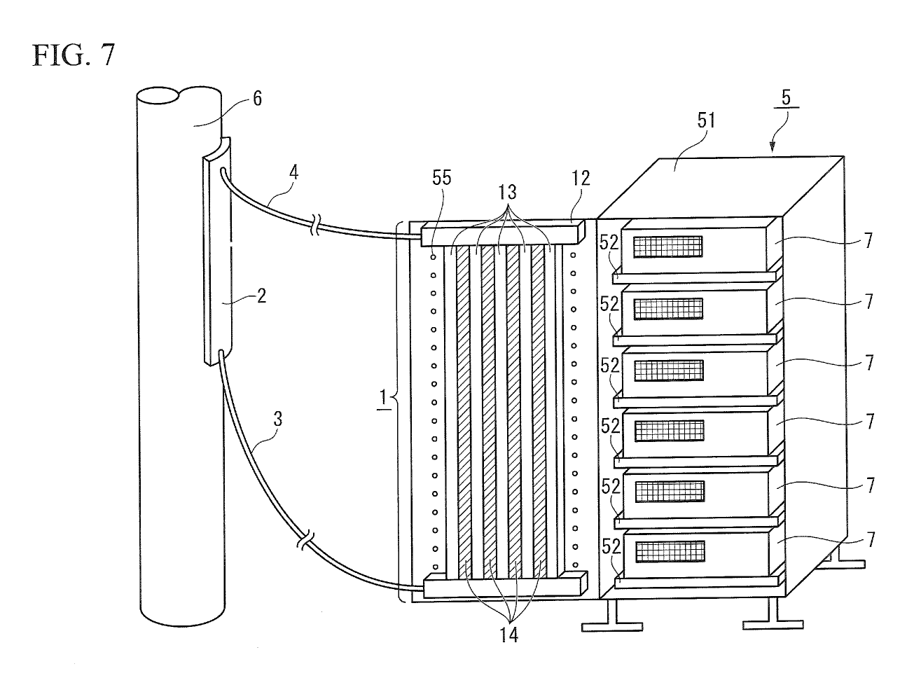

FIG. 7 is a perspective view of the system for cooling an electronic device according to the third exemplary embodiment of the present invention.

The system for cooling an electronic device according to the third exemplary embodiment differs from the first and second exemplary embodiments by the evaporator 1 being fixed to the rear door 53 of the storage rack 5. FIG. 7 shows the state of the rear door 53 being opened. When actually in use, the rear door 53 is in the closed state, whereby the evaporator 1 is made to face the fan of the electronic device 7.

According to this exemplary embodiment, the evaporator 1 is fixed to the rear door 53. For this reason, as shown in FIG. 7, when the rear door 53 is opened, it is possible to take out the electronic device 7 that is placed on the installation shelf 52. That is to say, according to the present exemplary embodiment, it is possible to replace the electronic device 7 from both the front and rear of the storage rack 5.

Hereinabove, exemplary embodiments of the present invention has been described in detail with reference to the drawings, but specific configurations are not limited to the aforementioned, and various design modifications can be made within a range that does not depart from the gist of this invention.

For example, in the first and second exemplary embodiments, although the case was described of providing a plurality of airtight systems including the evaporator 1, the condenser 2, and one pair of tubes 3 and 4, it is not limited to this. For example, just one airtight system may be provided that has the evaporator 1 at nearly the same height as the height of the housing 51. Similarly, in the third exemplary embodiment, although the case was described of providing just one airtight system including the evaporator 1, the condenser 2, and one pair of tubes 3 and 4, it is not limited to this. A plurality of airtight systems may also be provided in the same manner of the first and second exemplary embodiments.

Also, in the present exemplary embodiments, although the case was described of the condenser 2 being attached to a cooling pipe, it is not limited to this. Provided that the heat that the condenser 2 releases is discharged to outside of the server room or data center that is provided with the storage rack 5, it may be another cooling medium.

This application is based upon and claims the benefit of priority from Japanese patent application No. 2010-193733, filed Aug. 31, 2010, the disclosure of which is incorporated herein in its entirety by reference.

### INDUSTRIAL APPLICABILITY

The present invention can be applied to a system for cooling an electronic device. According to this system for cooling an electronic device, it is possible to cool air that is warmed by the discharge heat of an electronic device.

### REFERENCE SYMBOLS

1 Evaporator
2 Condenser
3, 4 Tube
5 Storage rack
6 Cooling water pipe (cooling pipe)
7 Electronic device
11 Lower container
12 Upper container
13 Evaporator tube
14 Heat receiving fin
15 Flow-in hole
16 Flow-out hole
21 Flow-in hole
22 Flow-out hole
23 Heat dissipating fin
24 TIM
51 Housing
52 Installation shelf
53 Rear door
54 Through hole
55 Exhaust hole

1. A system for cooling an electronic device that cools air warmed by exhaust heat of an electronic device, the system comprising:
an evaporator that is provided in a direction in which air is blown out by the electronic device, and causes a liquid coolant to undergo a phase transition to a gaseous coolant by absorbing heat of the air blown out from the electronic device;
a condenser that causes the gaseous coolant to undergo a phase transition to a liquid coolant by releasing heat of the gaseous coolant;
a gas flow channel that flows the gaseous coolant undergone the phase transition by the evaporator, into the condenser; and
a liquid flow channel that flows the liquid coolant undergone the phase transition by the condenser, into the evaporator,
the condenser arranged above the evaporator.

2. The system for cooling an electronic device according to claim 1, wherein at least one of the gas flow channel and the liquid flow channel extends gradually downward heading from the condenser to the evaporator.

3. The system for cooling an electronic device according to claim 1, wherein the condenser is provided on a surface of a cooling pipe through which circulates a fluid having a lower temperature than a boiling point of the gaseous coolant that is held in the condenser.

4. The system for cooling an electronic device according to claim 3, wherein at least a portion of the cooling pipe is exposed to outside of a room in which the electronic device is installed.

5. The system for cooling an electronic device according to claim 1, further comprising:
a storage rack that includes an installation shelf on which the electronic device is installed,
wherein the evaporator is provided in the direction in which air is blown out by the electronic device installed on the installation shelf, inside the storage rack, and
the condenser is provided outside the storage rack.

6. The system for cooling an electronic device according to claim 1, wherein the evaporator includes a heat receiving fin promoting heat exchange between the air that the electronic device blows out and the liquid coolant.

7. The system for cooling an electronic device according to claim 3, wherein the condenser includes a heat dissipating fin promoting heat exchange between the fluid and the gaseous coolant.

8. The system for cooling an electronic device according to claim 1, wherein the gas flow channel and the liquid flow channel are tubes having flexibility.

9. The system for cooling an electronic device according to claim 3, wherein the gas flow channel and the liquid flow channel connect the evaporator and the condenser via through holes that are provided in a side of the storage rack.

10. The system for cooling an electronic device according to claim 3,
wherein the storage rack includes a door attached so as to freely open and close to a side in the direction in which air is blown out by the electronic device, and
the evaporator is fixed to the door.

11. The system for cooling an electronic device according to claim 2, wherein the condenser is provided on a surface of a cooling pipe through which circulates a fluid having a lower temperature than a boiling point of the gaseous coolant that is held in the condenser.

12. The system for cooling an electronic device according claim 2, further comprising:
a storage rack that includes an installation shelf on which the electronic device is installed,
wherein the evaporator is provided in the direction in which air is blown out by the electronic device installed on the installation shelf, inside the storage rack, and
the condenser is provided outside the storage rack.

13. The system for cooling an electronic device according claim 3, further comprising:
a storage rack that includes an installation shelf on which the electronic device is installed,
wherein the evaporator is provided in the direction in which air is blown out by the electronic device installed on the installation shelf, inside the storage rack, and
the condenser is provided outside the storage rack.

14. The system for cooling an electronic device according claim 4, further comprising:
a storage rack that includes an installation shelf on which the electronic device is installed,
wherein the evaporator is provided in the direction in which air is blown out by the electronic device installed on the installation shelf, inside the storage rack, and
the condenser is provided outside the storage rack.

15. The system for cooling an electronic device according to claim 2, wherein the evaporator includes a heat receiving fin promoting heat exchange between the air that the electronic device blows out and the liquid coolant.

16. The system for cooling an electronic device according to claim 3, wherein the evaporator includes a heat receiving fin promoting heat exchange between the air that the electronic device blows out and the liquid coolant.

17. The system for cooling an electronic device according to claim 4, wherein the evaporator includes a heat receiving fin promoting heat exchange between the air that the electronic device blows out and the liquid coolant.

18. The system for cooling an electronic device according to claim 5, wherein the evaporator includes a heat receiving fin promoting heat exchange between the air that the electronic device blows out and the liquid coolant.

19. The system for cooling an electronic device according to claim 4, wherein the condenser includes a heat dissipating fin promoting heat exchange between the fluid and the gaseous coolant.

20. The system for cooling an electronic device according claim 2, wherein the gas flow channel and the liquid flow channel are tubes having flexibility.
